(19) United States
(12) Patent Application Publication
(10) Pub. No.: US 2026/0114188 A1
(43) Pub. Date: Apr. 23, 2026

(54) METAL NANOSHEET, METHOD FOR MANUFACTURING SAME, AND ALL-METAL THREE-TERMINAL ELECTRICAL SWITCHING DEVICE HAVING NOVEL STRUCTURE INCLUDING SAME

(71) Applicant: INDUSTRY-ACADEMIC COOPERATION FOUNDATION, YONSEI UNIVERSITY, Seoul (KR)

(72) Inventors: Woo Young SHIM, Seoul (KR); Dong Cheol SUH, Seoul (KR); Tae Hoon KIM, Seoul (KR)

(21) Appl. No.: 19/362,959

(22) Filed: Oct. 20, 2025

(30) Foreign Application Priority Data
Oct. 18, 2024 (KR) 10-2024-0143433
Oct. 2, 2025 (KR) 10-2025-0144351

(51) Int. Cl. H10N 70/20; H03K 19/00; H03K 19/01; H10N 70/00

(52) U.S. Cl. CPC H10N 70/253; H03K 19/0008; H03K 19/0021; H03K 19/01; H10N 70/021; H10N 70/881

(57) ABSTRACT

An embodiment relates to a method for manufacturing a metal nanosheet, including: providing a template having a two-dimensional layered structure with a limited interlayer height; and electroplating metal in an interlayer space of the template, wherein nucleation occurs in the interlayer space of the template, and the interlayer height is fixed.

### CROSS REFERENCE TO RELATED APPLICATIONS

This application claims priority from Korean Patent Application No. 10-2024-0143433, filed on Oct. 18, 2024, and Korean Patent Application No. 10-2025-0144351, filed on Oct. 2, 2025, in the Korean Intellectual Property Office, which is incorporated herein by reference in its entirety.

### BACKGROUND

The disclosure relates to a metal nanosheet, a method for manufacturing the same, and an all-metal three-terminal electrical switching device having a novel structure including the same, and more particularly, to a metal nanosheet having a very large electrical anisotropy that has not been seen in existing metals, such as other reported two-dimensional metals, by spatially limiting nucleation and growth to generate aligned grain boundaries, a method for manufacturing the same, and a novel structured all-metal three-terminal electrical switching device including the same.

Semiconductor transistors, a representative electrical switching device, have increased processing speed and efficiency by increasing device integration. However, physical limitations and heat generation are limiting their continued performance improvements. Consequently, the development of new, non-traditional material-based switching devices is essential.

### RELATED ART DOCUMENT

### Patent Document

Republic of Korea Publication Patent No. 2019-7021265

### SUMMARY

An aspect of the disclosure is to provide a metal nanosheet having a very large electrical anisotropy that has not been seen in other reported two-dimensional metals or other existing metals by spatially limiting nucleation and growth to generate aligned grain boundaries, a method for manufacturing the same, and an all-metal three-terminal electrical switching device having a novel structure including the same.

The aspect of the disclosure is not limited to that mentioned above, and other aspects not mentioned will be clearly understood by those skilled in the art from the description below.

An embodiment of the disclosure provides a method for manufacturing a metal nanosheet having in-plane electrical anisotropy.

The method for manufacturing a metal nanosheet having in-plane electrical anisotropy according to an embodiment of the disclosure may include:
providing a template having a two-dimensional layered structure with a limited interlayer height; and electroplating metal in an interlayer space of the template, wherein nucleation occurs in the interlayer space of the template, and the interlayer height is fixed.

In addition, according to an embodiment of the disclosure, the providing of the template may include, to fix the interlayer height, forming a pair of glass layers on the upper and lower surfaces of the template; and sealing three of the side surfaces of the template with epoxy resin.

In addition, according to an embodiment of the disclosure, the providing of the template may include: attaching a negative electrode to one end of the template; and connecting a wire to the negative electrode.

In addition, according to an embodiment of the disclosure, in the electroplating of the metal, nucleation may occur on the surface of the negative electrode, and ion diffusion may proceed through the interlayer space of the template, resulting in unidirectional crystal growth.

In addition, according to an embodiment of the disclosure, a grain boundary of the metal plated through the electroplating of the metal may be aligned parallel to the upper and lower surfaces of the template.

In addition, according to an embodiment of the disclosure, the interlayer height of the template may be greater than the ion size of the metal to be plated, but smaller than the ion size of the metal in its hydrated state.

In addition, according to an embodiment of the disclosure, the interlayer height of the template may be 2.5 Å to 7.5 Å.

In addition, according to an embodiment of the disclosure, the template, which is an insulator having a two-dimensional van der Waals gap, may be composed of one or more selected from the group consisting of graphene oxide (GO), vermiculite, and boron nitride (hBN).

In addition, according to an embodiment of the disclosure, the metal may include one or more selected from the group consisting of Mg, Al, Cr, Mn, Fe, Co, Ni, Cu, Zn, Rb, Sr, Ag, Cd, Cs, Ba, La, and Pb.

Another embodiment of the disclosure provides a metal nanosheet having in-plane electrical anisotropy.

The metal nanosheet having in-plane electrical anisotropy according to an embodiment of the disclosure
is formed by the above-described method for manufacturing a metal nanosheet and has in-plane electrical anisotropy.

In addition, according to an embodiment of the disclosure, the metal may include one or more selected from the group consisting of Mg, Al, Cr, Mn, Fe, Co, Ni, Cu, Zn, Rb, Sr, Ag, Cd, Cs, Ba, La, and Pb.

Another embodiment of the disclosure provides an all-metal three-terminal electrical switching device.

The all-metal three-terminal electrical switching device according to an embodiment of the disclosure may include: a metal nanosheet having in-plane electrical anisotropy; and a plurality of electrodes connected to the metal nanosheet,
wherein the plurality of electrodes include: a source electrode; a first drain electrode (⊥); and a second drain electrode (∥).

In addition, according to an embodiment of the disclosure, the metal nanosheet having in-plane electrical anisotropy may have higher electrical conductivity in a direction parallel to the grain alignment axis than in a direction perpendicular to the grain alignment axis.

In addition, according to an embodiment of the disclosure, the first drain electrode (⊥) may be connected in a direction parallel to the grain alignment axis of the metal nanosheet, and the second drain electrode (∥) may be connected in a direction perpendicular to the grain alignment axis of the metal nanosheet.

In addition, according to an embodiment of the disclosure, the on/off ratio of the switching device may be determined by formula 1:

$$1 + \frac{Rxx V ⊥ d}{Ryy V \vert \vert d} \qquad [ Equation 1 ]$$

In addition, according to an embodiment of the disclosure, the on/off ratio of the switching device may be 10⁷ or more.

In addition, according to an embodiment of the disclosure, in the switching device,
the magnitude of a current (Iₛ) flowing through the device changes according to a voltage applied to the first drain electrode (⊥) and the second drain electrode (∥), if the magnitude of the current (Iₛ) is less than a predetermined threshold (threshold current), it is defined as an off state, and if it exceeds the threshold, it is defined as an on state.

In addition, according to an embodiment of the disclosure, the threshold may be set within the range of 10⁻⁹ A to 10⁻⁶ A.

In addition, according to an embodiment of the disclosure, in the switching device, by setting the application conditions of the first drain voltage (V_{d}^{⊥}) and the second drain voltage (V_{d}^{∥}),
one of logical operations composed of AND, OR, NAND, NOR, XOR, and XNOR may be implementable.

According to an embodiment of the disclosure, by spatially limiting nucleation and growth to generate aligned grain boundaries, a metal nanosheet having a very large electrical anisotropy not seen in existing metals, such as other reported two-dimensional metals, a method for manufacturing the same, and a novel structure of an all-metal three-terminal electrical switching device including the same can be provided.

According to an embodiment of the disclosure, an electroplating method using the template of the disclosure can be easily applied and expanded to various metals.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view illustrating a manufacturing process of a method for manufacturing a metal nanosheet with in-plane electrical anisotropy according to an embodiment of the disclosure, compared to a conventional method;

FIG. 2 is a schematic view illustrating the manufacturing principle of a method for manufacturing a metal nanosheet with in-plane electrical anisotropy according to an embodiment of the disclosure, compared to a conventional method;

FIG. 3 is a schematic view illustrating the overall structure of a method for manufacturing a metal nanosheet with in-plane electrical anisotropy according to an embodiment of the disclosure;

FIG. 4 is an actual photograph of a template applied in a method for manufacturing a metal nanosheet with in-plane electrical anisotropy according to an embodiment of the disclosure;

FIG. 5 is a graph illustrating the ion sizes of different metal types, the ion sizes of the metals in their hydrated state, and the interlayer spacing of graphene oxide (GO);

FIG. 6 shows images of a metal nanosheet with in-plane electrical anisotropy according to an embodiment of the disclosure and a typical metal nanosheet, each with electrodes attached in 12 directions;

FIG. 7 shows data obtained by measuring the electrical conductivity of a metal nanosheet with in-plane electrical anisotropy according to an embodiment of the disclosure in FIG. 6 and a typical metal nanosheet in each direction;

FIG. 8 shows STEM images of the y-z plane (Zones 1 to 3) and x-z plane (Zones 4 to 6) at various magnifications of a cross-section of a metal nanosheet with in-plane electrical anisotropy according to an embodiment of the disclosure;

FIG. 9 shows (a) an image and (b) a schematic view of an all-metal three-terminal electrical switching device according to an embodiment of the disclosure;

FIGS. 10A and 10B show experimental data analyzing the characteristics of an all-metal three-terminal electrical switching device according to an embodiment of the disclosure;

FIG. 11 is a graph showing that the mathematical prediction of the device's on/off ratio according to the applied voltage matches experimental data, and that the on/off ratio can be increased by up to 10⁷ times or more depending on the driving voltage;

FIG. 12 is a graph showing the current (Iₛ) value according to the first drain voltage (V_{d}^{⊥}) and second drain voltage (V_{d}^{∥}); and

FIGS. 13A to 13F include a graph illustrating the relationship between the input voltage (V_{d}^{⊥}, V_{d}^{∥}) and the output current (Iₛ) for each of the six rectangular areas indicated in FIG. 12, and examples of implementing each logical operation based on this relationship, wherein

FIG. 13A shows the AND logic circuit and its output characteristics, FIG. 13B shows the input signal variation over time for an AND logic circuit and the resulting output waveform,

FIG. 13C shows the OR logic circuit and its output characteristics, FIG. 13D shows the input signal variation over time for an OR logic circuit and the resulting output waveform,

FIG. 13E shows the NAND logic circuit and its output characteristics, FIG. 13F shows the input signal variation over time for a NAND logic circuit and the resulting output waveform,

FIG. 13G shows the NOR logic circuit and its output characteristics, FIG. 13H shows the input signal variation over time for a NOR logic circuit and the resulting output waveform,

FIG. 13I shows the XNOR logic circuit and its output characteristics, FIG. 13J shows the input signal variation over time for an XNOR logic circuit and the resulting output waveform,

FIG. 13K shows the XOR logic circuit and its output characteristics, and FIG. 13L shows the input signal variation over time for an XOR logic circuit and the resulting output waveform.

### DETAILED DESCRIPTION

Hereinafter, the disclosure will be described with reference to the accompanying drawings. However, the disclosure may be implemented in various different forms and therefore is not limited to the embodiments described herein, but should be understood to include all modifications, equivalents, or substitutes included in the spirit and technical scope of the disclosure.

In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between.

In addition, when a part such as a layer, film, region, or plate is said to be “on” another part, this includes not only the case where it is “directly on” another part, but also the case where there is another part in between. In addition, in this specification, when a part such as a layer, film, region, or plate is formed on another part, the direction in which it is formed is not limited to the upper direction, and includes being formed in the side or lower direction. On the other hand, when a part such as a layer, film, region, or plate is said to be “under” another part, this includes not only the case where it is “directly under” another part, but also the case where there is another part in between.

In this specification, the terms “upper surface” and “lower surface” are used as relative concepts in order to easily explain the technical idea of the disclosure. Therefore, the terms “upper surface” and “lower surface” do not refer to a specific direction, position, or component, and are interchangeable with each other.

For example, the “upper surface” may be interpreted as the “lower surface,” and the “lower surface” may be interpreted as the “upper surface.” Therefore, the “upper surface” may be expressed as “first” and the “lower surface” may be expressed as “second”, or the “lower surface” may be expressed as “first” and the “upper surface” may be expressed as “second”. However, within one embodiment, the terms “upper surface” and “lower surface” are not used interchangeably.

Unless otherwise defined, all terms used herein, including technical or scientific terms, have the same meaning as generally understood by a person of ordinary skill in the art to which the disclosure belongs. Terms defined in commonly used dictionaries should be interpreted as having a meaning consistent with the meaning they have in the context of the relevant technology, and shall not be interpreted in an ideal or overly formal sense unless explicitly defined in this application.

In addition, when a part is said to “include” a certain component, this does not exclude other components unless specifically stated to the contrary, but rather means that other components may be additionally provided.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings.

First, a method for manufacturing a metal nanosheet with in-plane electrical anisotropy according to an embodiment of the disclosure will be described.

The electrical properties of a material generally depend on its unique crystal structure. For example, copper, which has an isotropic cubic structure, exhibits high electrical conductivity regardless of orientation, while graphene, which has a two-dimensional layered structure, exhibits significant differences in electrical conductivity in directions parallel and perpendicular to the layered structure. This difference in electrical conductivity along different directions is called electrical anisotropy, and is considered a unique characteristic of each material.

The disclosure provides a method for synthesizing metal nanosheets with in-plane electrical anisotropy through specific grain alignment.

In the disclosure, a template with a layered structure is used to grow a metal in a two-dimensional manner and metal nanosheets grown in the interlayer space of the layered template have grain boundaries uniformly aligned along the metal growth direction.

This enables the implementation of high (>103) electrical anisotropy even in metallic materials with a high-symmetry cubic crystal structure.

The disclosure may provide a metallic electrical switching device based on metal nanosheets that exhibit in-plane electrical anisotropy at a level not seen in conventional monoatomic metals.

As an example of the embodiment, there may be a method for manufacturing metal nanosheets with in-plane electrical anisotropy, including: providing a template having a two-dimensional layered structure with a limited interlayer height; and a step of electroplating metal in the interlayer space of the template,
wherein nucleation occurs in the interlayer space of the template and the interlayer height is fixed.

Through the above embodiment, since high electrical anisotropy can be achieved even with metal materials having a high-symmetry cubic crystal structure, the two-dimensional metal nanosheets synthesized using this method exhibit high anisotropy and overcome the limitations of thickness-dependent two-dimensional materials.

At this time, despite their cubic crystal structure, the metal nanosheets exhibit high electrical anisotropy, expressed as Gₘₐₓ/Gₘᵢₙ (=G_{yy}/Gₓₓ), with a maximum electrical anisotropy of 3700 or higher.

As described above, the two-dimensional metal nanosheets synthesized using the nanosheet manufacturing method according to the embodiments of the disclosure can achieve high electrical anisotropy through microstructural control and grain orientation engineering.

This allows for high electrical anisotropy, exceeding the level of anisotropy limited by the intrinsic properties of existing materials, compared to low-symmetry crystal structures (Tetragonal, Monoclinic, Orthorhombic, Triclinic, Hexagonal, Trigonal) typically utilized to achieve electrical anisotropy, or ternary or higher compounds, where atomic structure anisotropy increases with increasing element count;
furthermore, this structure offers the potential for expansion to other materials. In addition, these metal nanosheets not only exhibit high electrical anisotropy but also exhibit electrical anisotropy in the in-plane direction, offering the potential for application as orthogonal elements in switching devices.

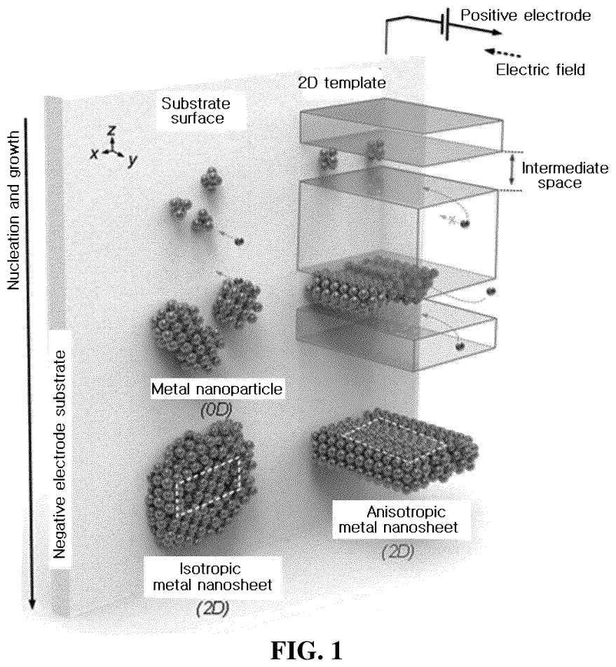

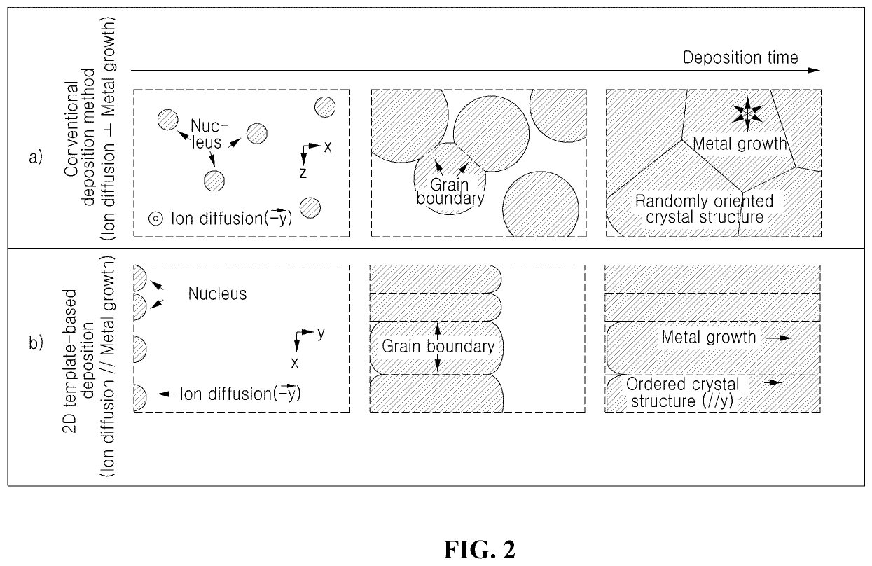

This will be described in more detail below with reference to FIGS. 1 and 2.

FIG. 1 is a schematic view illustrating a manufacturing process of a method for manufacturing a metal nanosheet with in-plane electrical anisotropy according to an embodiment of the disclosure, compared to a conventional method.

FIG. 2 is a schematic view illustrating the manufacturing principle of a method for manufacturing a metal nanosheet with in-plane electrical anisotropy according to an embodiment of the disclosure, compared to a conventional method.

Referring to FIGS. 1 and 2,
a comparison can be made between a metal structure fabricated on a conventional flat surface and a metal structure fabricated using a two-dimensional template used in the disclosure.

It can be confirmed that the metal nanosheets obtained by electroplating on a conventional flat surface exhibit an isotropic crystal structure with random nucleation of ions on the substrate and randomly oriented grain boundaries.

In contrast,
as in the above embodiment, the metal nanosheets fabricated by electroplating within a two-dimensional template with a limited interlayer spacing (height) exhibit aligned grain boundaries.

Furthermore, in electroplating using a two-dimensional template, nucleation occurs only on the negative electrode surface at the template tip, causing nuclei to grow in one direction, and this difference may lead to the formation of an anisotropic microstructure with parallel, aligned grain boundaries within the sheet.

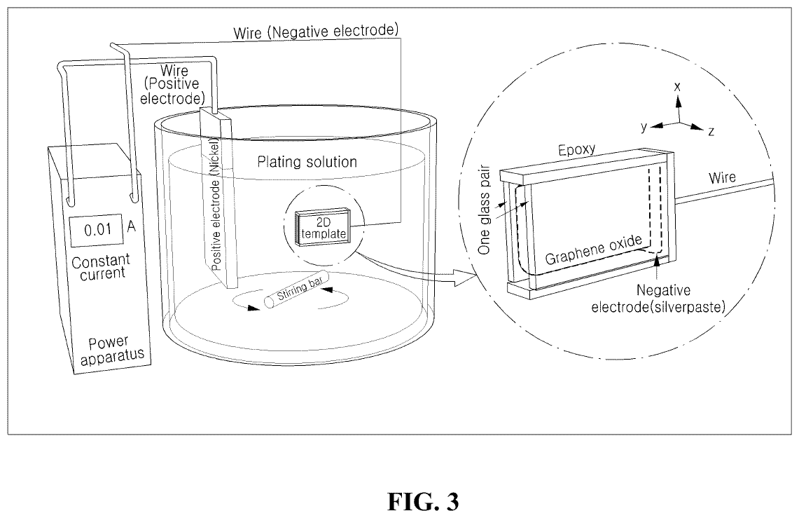

FIG. 3 is a schematic view illustrating the overall structure of a method for manufacturing a metal nanosheet with in-plane electrical anisotropy according to an embodiment of the disclosure.

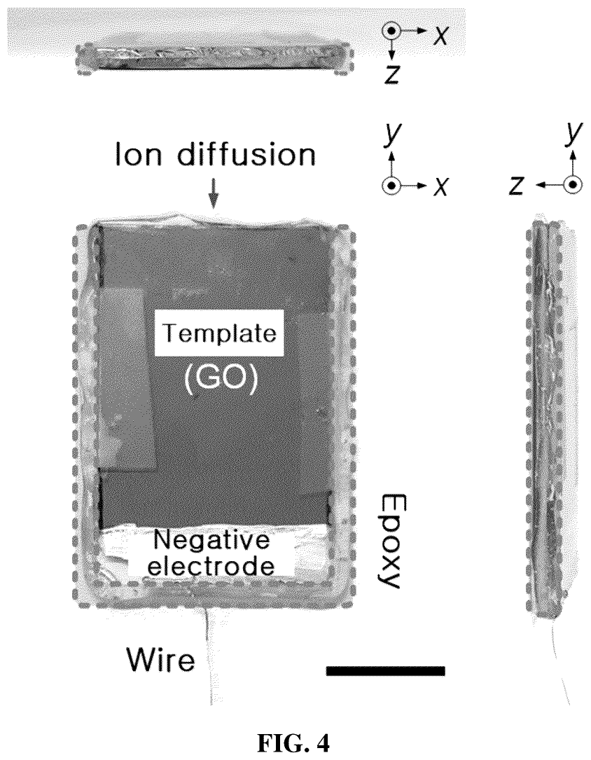

FIG. 4 is an actual photograph of a template applied in a method for manufacturing a metal nanosheet with in-plane electrical anisotropy according to an embodiment of the disclosure.

Referring to FIGS. 3 and 4, as an example of the above embodiment, the providing of the template may include, to fix the interlayer height,
forming a pair of glass layers on the upper and lower surfaces of the template; and sealing three of the side surfaces of the template with epoxy resin.

Here, the providing of the template may include:
attaching a negative electrode to one end of the template; and connecting a wire to the negative electrode.

When the template is provided as shown in FIG. 4 and electroplating is performed as shown in FIG. 3, nucleation occurs on the surface of the negative electrode, and ion diffusion proceeds through the interlayer space of the template, allowing unidirectional crystal growth to occur.

Furthermore, referring to FIG. 2, it can be confirmed that the grain boundaries of the metal plated through the step of electroplating are aligned parallel to the upper and lower surfaces of the template.

Through this process, after complete growth, the grain boundaries within the sheet are uniformly aligned, forming an anisotropic microstructure.

As an example of the above embodiment, there may be a method for manufacturing a metal nanosheet having in-plane electrical anisotropy, wherein the interlayer height of the template is greater than the ion size of the metal to be plated, but less than the ion size of the metal in its hydrated state.

As in the above embodiment, when the channel size (layer height, interlayer spacing) is smaller than the critical nucleation size (the size of ions in the hydrated metal), local nucleation and limited particle growth are possible.

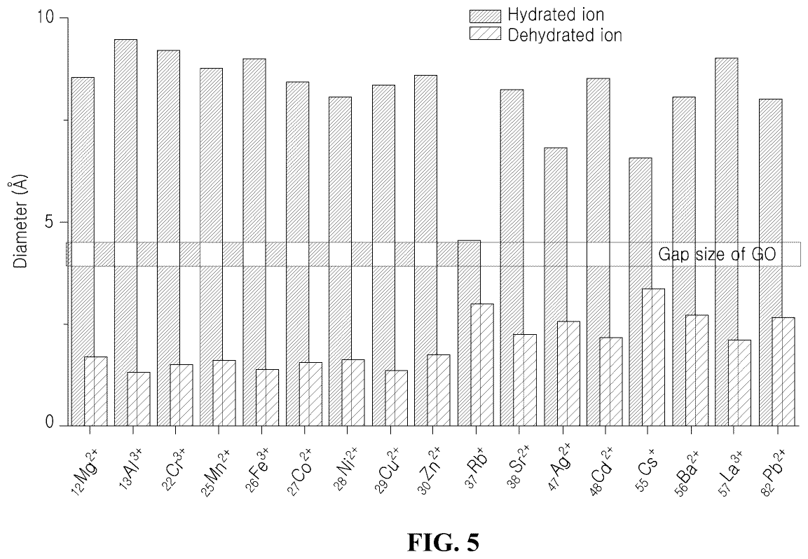

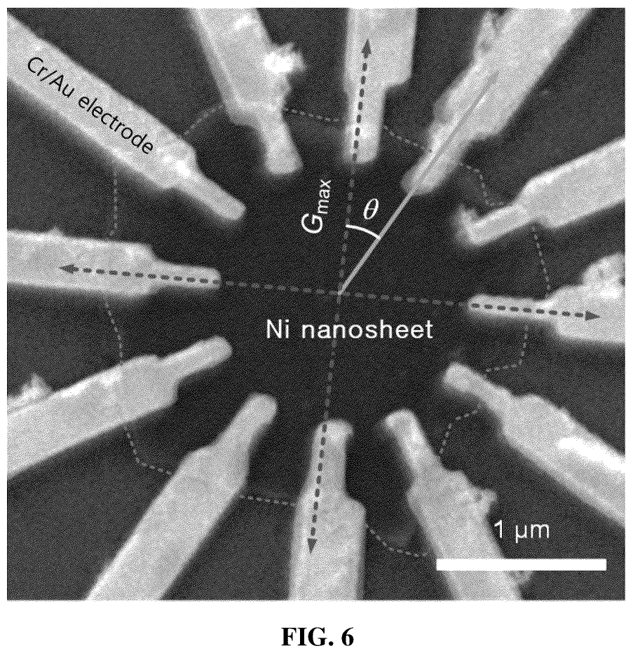

FIG. 5 is a graph illustrating the ion sizes of different metal types, the ion sizes of the metals in their hydrated state, and the interlayer spacing of graphene oxide (GO).

Referring to FIG. 5, the interlayer heights of the templates implementable depending on the type of metal can be confirmed.

Referring to FIG. 5, there may be a method for manufacturing metal nanosheets with in-plane electrical anisotropy, wherein the interlayer height of the template usable in the above embodiment is 2.5 Å to 7.5 Å.

More preferably, the interlayer height may be 4 Å to 7.5 Å.

Most preferably, the interlayer height may be 4 Å to 6 Å.

Referring to FIG. 5, it can be confirmed that the above-described effects can be achieved for the widest variety of metals when the layer height of the template is 4 Å to 6 Å.

As an example of the above embodiment, there may be a method for manufacturing metal nanosheets with in-plane electrical anisotropy, wherein the template includes an insulator having a two-dimensional van der Waals gap, and is composed of at least one insulator selected from the group consisting of two-dimensional atomic structures, such as graphene oxide (GO), vermiculite, and hBN.

At this time, only when an insulator is used as the template can ions be reduced only on the negative electrode surface.

If a conductor, rather than an insulator, is used as the template, the template surface may supply electrons to the ions, potentially leading to metal reduction at undesirable locations.

Furthermore, as described above, the template must be an insulator with a two-dimensional van der Waals gap and a two-dimensional atomic structure.

While three-dimensional insulators, such as silicon oxide, cannot have a uniform interlayer height that allows metal ion movement,
an insulator with a two-dimensional atomic structure possesses a uniform interlayer height (van der Waals gap) that allows metal ion movement, making it an essential element for the growth of aligned metal nanosheets.

Furthermore, as an example of the above embodiment, a method for manufacturing a metal nanosheet with in-plane electrical anisotropy may be provided, characterized in that the metal includes at least one selected from the group consisting of Mg, Al, Cr, Mn, Fe, Co, Ni, Cu, Zn, Rb, Sr, Ag, Cd, Cs, Ba, La, and Pb, as shown in FIG. 5.

A metal nanosheet according to another embodiment of the disclosure will be described.

As an example of the above embodiment, there may be a metal nanosheet formed using the aforementioned method for manufacturing a metal nanosheet, and having in-plane electrical anisotropy.

Furthermore, the metal nanosheet may be characterized by being composed of one or more metals selected from the group consisting of Mg, Al, Cr, Mn, Fe, Co, Ni, Cu, Zn, Rb, Sr, Ag, Cd, Cs, Ba, La, and Pb.

Since the metal nanosheet is a different category of invention with substantially the same technical structure as the metal nanosheet manufacturing method,
it is noted that the aforementioned descriptions of the metal nanosheet manufacturing method are applicable as is.

An all-metal three-terminal electrical switching device according to another embodiment of the disclosure will be described.

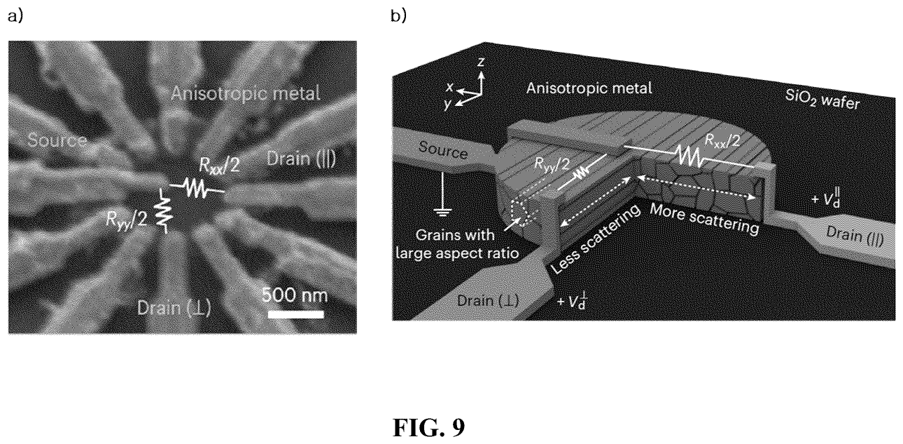

FIG. 9 shows an image and a schematic view of an all-metal three-terminal electrical switching device according to an embodiment of the disclosure.

Referring to FIG. 9, as an example of the embodiment, there may be an all-metal three-terminal electrical switching device, including: a metal nanosheet having in-plane electrical anisotropy; and a plurality of electrodes connected to the metal nanosheet,
wherein the plurality of electrodes include: a source electrode; a first drain electrode (⊥); and a second drain electrode (∥).

As an example of the embodiment, the first drain electrode (⊥) may be connected in a direction parallel to the grain alignment axis of the metal nanosheet, and the second drain electrode (∥) may be connected in a direction perpendicular to the grain alignment axis of the metal nanosheet.

At this time, the source electrode may face the second drain electrode (∥) and be connected in a direction perpendicular to the grain alignment axis of the metal nanosheet.

The all-metal switching device according to the above embodiment utilizes a metal nanosheet having in-plane electrical anisotropy, and
the metal nanosheet may be characterized by a high electrical anisotropy (Gₘₐₓ/Gₘᵢₙ) of up to 3700 or greater, despite having a cubic crystal structure.

That is, the metal nanosheet having in-plane electrical anisotropy may be characterized by high conductivity in a direction parallel to the grain alignment axis and low conductivity in a direction perpendicular to the grain alignment axis.

Regarding this, the on/off ratio of the switching device may be determined by formula 1.

$$1 + \frac{Rxx V ⊥ d}{Ryy V \vert \vert d} \qquad [ Equation 1 ]$$

In the switching device described above, the on/off ratio is a key indicator of device performance, and it is defined as the ratio of the current flowing in the ON state (Iₒₙ) to the current flowing in the OFF state (I_{off}).

A higher ON/OFF ratio clearly differentiates the current between the ON and OFF states, enabling stable distinction between logic signals “1” and “0” in digital circuits and maintaining a high signal-to-noise ratio (SNR).

In addition, when the on/off ratio is large, the leakage current in the off state is reduced, which can reduce power consumption and heat generation, thereby improving the operating speed and integration level of the device.

The switching device according to the above embodiment may be characterized by an on/off ratio of 10⁷ or greater according to formula 1.

Therefore, when external power is applied in a direction parallel to the grain boundary alignment axis, current flow increases by 10⁷ times or more compared to when external power is applied, enabling the on/off state to be distinguished, similar to a semiconductor transistor.

In the switching device according to the above embodiment, the on/off ratio (change in current flow due to external power application) is affected by 1) the resistance difference (electrical conductivity difference) between the vertical and parallel directions, as well as 2) the applied voltage.

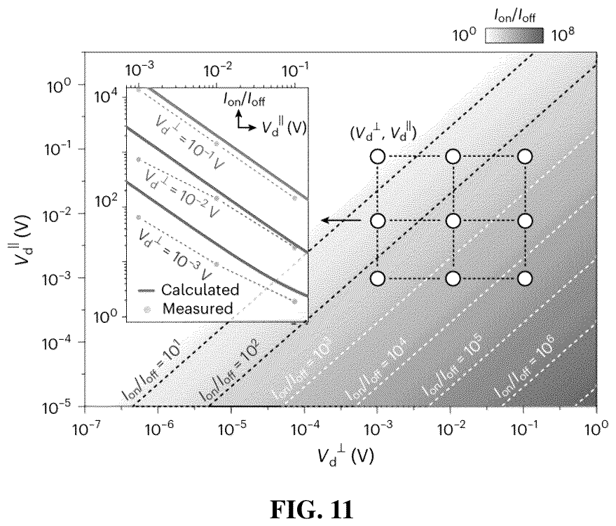

This can be explained using formula 1 and FIG. 11.

Formula 1 above is a formula indicating that the on/off ratio of the device is determined by the resistance difference (Rₓₓ/R_{yy}) between the vertical and parallel directions and the applied voltage (V_{d}^{⊥}/V_{d}^{∥}).

FIG. 11 is a graph showing that the mathematical prediction of the device's on/off ratio according to the applied voltage matches experimental data, and that the on/off ratio can be increased by up to 10⁷ times or more depending on the driving voltage.

More specifically, for a device with a resistance difference of 200 times or more between directions parallel and perpendicular to the grain alignment axis,
when the driving voltage was varied from 10⁻⁷ V to 1 V for the first drain voltage (V_{d}^{⊥}) and
from 10⁻⁵ V to 1 V for the second drain voltage (V_{d}^{∥}),
the device's on/off ratio was mathematically calculated using formula 1, and it was confirmed that it increased by up to 10⁷ times under the conditions of V_{d}^{⊥}=1 V, V_{d}^{∥}=10⁻⁵ V.

Additionally, referring to FIG. 11, for the corresponding device,
for the first drain voltage (V_{d}^{⊥}), one of three driving voltages (10⁻³ V, 10⁻² V, 10⁻¹ V) was selected,
for the second drain voltage (V_{d}^{∥}), one of three driving voltages (10⁻³ V, 10⁻² V, 10⁻¹ V) was selected, and
the on/off ratio was experimentally measured for a total of nine driving voltage combinations corresponding to the rectangular areas in the graph, and compared with mathematical calculations.

As a result, the experimental measurements showed an on/off ratio of up to 10⁴ times greater under conditions of V_{d}^{⊥}=10⁻¹ V, V_{d}^{∥}=10⁻³ V, and as shown in the inset graph, the agreement between the experimental measurements and mathematical calculations confirms the validity of the theoretical calculations.

Furthermore, as an example of the above embodiment, the switching device may be characterized in that the magnitude of the current (Iₛ) flowing through the device varies depending on the voltage applied to the first drain electrode (⊥) and the second drain electrode (∥), and that if the magnitude of the current (Iₛ) is below a threshold current, the device is in an off state, and if it exceeds the threshold current, the device is in an on state.

At this time, the threshold current may be set within a range of 10⁻⁹ A to 10⁻⁶ A.

If the threshold is set too low, below 10⁻⁹ A, external noise or leakage current can easily exceed the threshold, potentially resulting in false switching.

Conversely, if the threshold is set too high, exceeding 10⁻⁶ A, excessive current is required to drive the device itself, increasing power consumption and degrading the stability of logic operations.

As described above, the switching device may be characterized by being capable of implementing any one of the logical operations, AND, OR, NAND, NOR, XOR, and XNOR, depending on the application conditions of the first drain voltage (V_{d}^{⊥}) and the second drain voltage (V_{d}^{∥}).

That is, a device according to an example embodiment of the disclosure uses the first drain voltage (V_{d}^{⊥}) and the second drain voltage (V_{d}^{∥}) as input signals (two-input), and compares the output current (Iₛ) with a threshold current to determine whether it is 0 or 1, and this allows a single device to reliably implement six logic gates (AND, OR, NAND, NOR, XOR, XNOR).

At this time, depending on the input values of the first drain voltage (V_{d}^{⊥}) and the second drain voltage (V_{d}^{∥}), the output current (Iₛ) is classified as being above or below the threshold value, thereby consistently corresponding to the truth table of the logic operation, and thus it is sufficient to reliably implement logic operations such as AND, OR, NAND, NOR, XOR, and XNOR; however, this requirement is not limited to the specific voltage values exemplified in the embodiments.

Specific embodiments are described in detail in experimental example 3 below.

Furthermore, unlike conventional semiconductor transistors, which incorporate a dielectric layer and utilize the charge/discharge effect of an electric field to induce electrons in the channel and change the current flow,
the all-metal three-terminal electrical switching device does not include a dielectric layer and therefore operates without charging/discharging, and utilizes an anisotropic conduction path as the channel, changing the current flow depending on channel activation.

This allows for low-voltage operation without a theoretical operating voltage, and furthermore, switching speeds can be increased by eliminating the RC delay caused by resistance and capacitance in the device operation mechanism.

By utilizing a metal nanosheet with aligned crystal grains, with an increased on/off ratio due to electrical anisotropy, electrical anisotropy can be maximized, and an on/off ratio of up to 10⁷ times or more can be achieved.

These switching characteristics offer the advantage of enabling logical operations in a single device.

Manufacturing example 1. Manufacturing of metal (Ni) nanosheets with in-plane electrical anisotropy.
Manufacturing example 1 will be described with reference to FIGS. 3 and 4.
Graphene oxide was prepared by dropping a highly concentrated graphene oxide solution (5 g/L; Graphene Supermarket) onto a glass slide until the film height reached 20 μm. The solution was then dried at room temperature for 24 hours.
Silver paste electrodes and copper wires were attached to the ends of the graphene oxide.
The graphene oxide was placed between two glass slides, and the gap between the two slides, including the three corners, was covered with commercial epoxy (S-208, DEVCON).
The epoxy was then dried at room temperature for 24 hours.
A nickel plate was used as the negative electrode, and the prepared graphene oxide template served as the positive electrode.
The electrolyte was prepared using deionized water (DI) containing 80 g/L of NiSO₄·6H₂O, 40 g/L of NiCl₂·6H₂O, and 30 g/L of H₃BO₃.
A constant current of 0.01 A was supplied for 24 hours via a power supply device.

### Experimental Example 1. Analysis of Electrical Conductivity Characteristics According to The Direction and Thickness of Metal Nanosheet According to an Embodiment of the Disclosure

FIG. 6 shows images of a metal nanosheet with in-plane electrical anisotropy according to an embodiment of the disclosure and a typical metal nanosheet, each with electrodes attached in 12 directions.

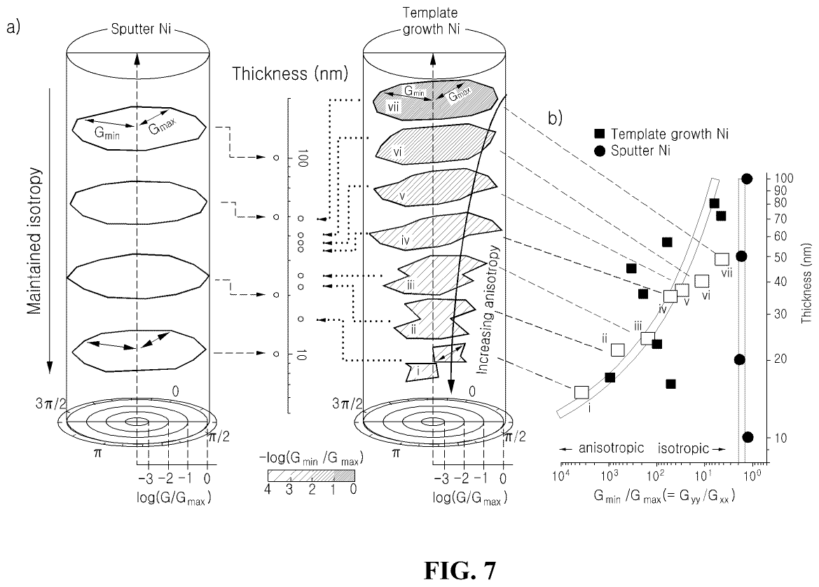

FIG. 7 shows data obtained by measuring the electrical conductivity of a metal nanosheet with in-plane electrical anisotropy according to an embodiment of the disclosure in FIG. 6 and a typical metal nanosheet in each direction.

In experimental example 1, the graphene oxide template filled with metal nanosheets was mechanically exfoliated from a silicon oxide substrate using Scotch tape, and the graphene oxide containing the metal nanosheets was heated to 350° C.

This process removed the graphene oxide, leaving only the anisotropic metal nanosheets on the silicon oxide substrate.

Thereafter, as shown in FIG. 6, 12-directional electrodes were fabricated on the metal nanosheets, conductivity was measured along these directions, and the anisotropic conductivity differences across the metal nanosheets were identified.

Additionally, the isotropic conductivity of metal nanosheets fabricated using a conventional deposition method (sputtering) was confirmed, allowing comparison with the anisotropy of the metal nanosheets of the disclosure.

At this time, the regions indicated in FIGS. 6 and 7 represent the directions of maximum nanosheet conductivity, respectively.

As shown in FIG. 6, 12 electrodes were fabricated around a Ni nanosheet at 30° intervals, and the electrical conductivity was measured.

As a result, as shown in FIG. 7, the electrical conductivity decreased to 1,265 μS at θ=0, 968 μS at π/6, 955 μS at π/3, and 25 μS at π/2, before increasing again at θ=π.

This demonstrates the varying conductivity of a single nanosheet depending on the grain boundary orientation, demonstrating a nearly 50-fold difference in electrical conductivity between conduction parallel to the grain boundary (θ=0) and conduction perpendicular to the grain boundary (θ=π/2).

Furthermore, FIG. 7 demonstrates the thickness dependence of the angle-resolved conductivity of conventional sputter deposition and template-mediated nanosheets, and
electrical anisotropy (Gₘₐₓ/Gₘᵢₙ) and trends of sputtered (circular) and templated (square) nanosheets according to sample thickness can be observed.

At this time, while conventional techniques (sputtered Ni) maintain isotropy regardless of thickness,
the template-grown metal (Ni) nanosheets according to the disclosure exhibit anisotropy from the outset, regardless of thickness, and the anisotropy gradually increases as the thickness decreases.

Thus, the metal (Ni) nanosheets according to the disclosure enables to confirm that the in-plane electrical anisotropy of the metal nanosheets can be controlled by adjusting the thickness.

More specifically, when the metal nanosheets have a thickness of 10 nm to 60 nm, the metal nanosheets are characterized by an anisotropy value of 10 or greater, as determined by formula 2.

$$Anisotropy value = {G}_{max} / {G}_{min} ( = {G}_{yy} / {G}_{x x} ) \qquad [ Formula 2 ]$$

In formula 2, Gₘₐₓ represents the highest electrical conductivity measured on the corresponding surface, and Gₘᵢₙ represents the lowest electrical conductivity measured on the corresponding surface.

Furthermore, when the metal nanosheet has a thickness of 10 nm to 30 nm, the metal nanosheet may be characterized by an anisotropy value of 100 or greater according to formula 2.

When the metal nanosheet has a thickness of 10 nm to 20 nm, the metal nanosheet may be characterized by an anisotropy value of 1000 or greater according to formula 2.

Through experimental example 1, the electrical conductivity was measured along different directions, and cross-sections in directions with high electrical conductivity and those with low conductivity were examined, confirming that the cross-sections had grain boundary differences.

### Experimental Example 2. Analysis of the Cross-Sectional Structure of a Metal Nanosheet According to an Embodiment of the Disclosure

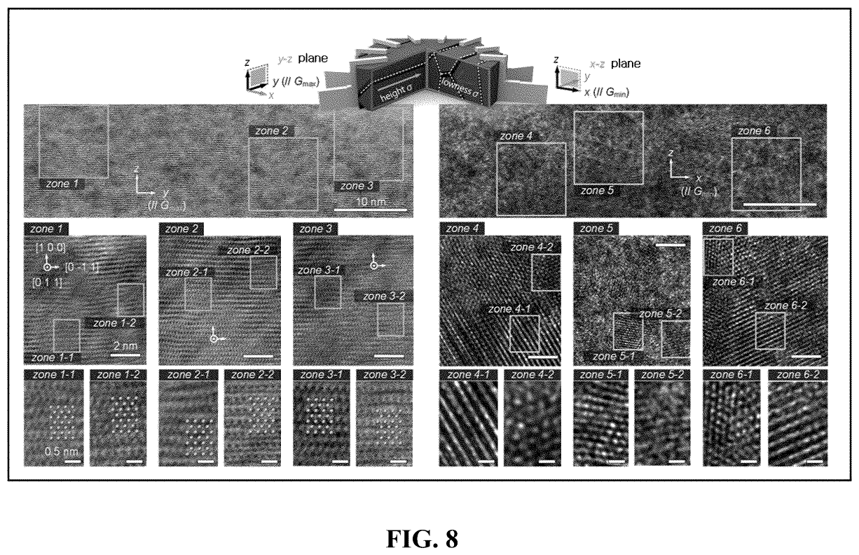

FIG. 8 shows STEM images of the y-z plane (Zones 1 to 3) and x-z plane (Zones 4 to 6) at various magnifications of a cross-section of a metal nanosheet with in-plane electrical anisotropy according to an embodiment of the disclosure.

FIG. 8 shows the microstructural differences between the two samples through TEM analysis (BF-STEM and high-resolution TEM).

Referring to the STEM images in the y-z plane (Zones 1 to 3), the samples exhibit the geometry and symmetry of the [0 1 1] plane of FCC Ni, with a consistent periodic structure and fewer grain boundaries.

This indicates non-uniform nucleation and growth primarily along the y-direction at the positive electrode surface.

Conversely, the STEM images in the x-z plane (Zones 4 to 6) reveal a random grain distribution with diverse orientations.

This suggests a correlation between grain orientation and conductivity anisotropy.

### Experimental Example 3. Analysis of Switch Characteristics of an all-Metal Three-Terminal Electrical Switching Device According to an Embodiment of the Disclosure

FIG. 9 shows an image and a schematic view of an all-metal three-terminal electrical switching device according to an embodiment of the disclosure.

Referring to FIG. 9, the structure of an all-metal three-terminal electrical switching device according to an embodiment of the disclosure can be confirmed, and
the all-metal three-terminal electrical switching device is an all-metal device that uses an external voltage to adjust the current.

At this time, the on-off ratio of the all-metal three-terminal electrical switching device is as shown in formula 1.

$$1 + \frac{Rxx V ⊥ d}{Ryy V \vert \vert d} \qquad [ Equation 1 ]$$

In formula 1, Rₓₓ is the electrical resistance in the direction perpendicular to the grain boundary alignment direction (high resistance), and

R_{yy} is the electrical resistance in the direction parallel to the grain boundary alignment direction (low resistance).

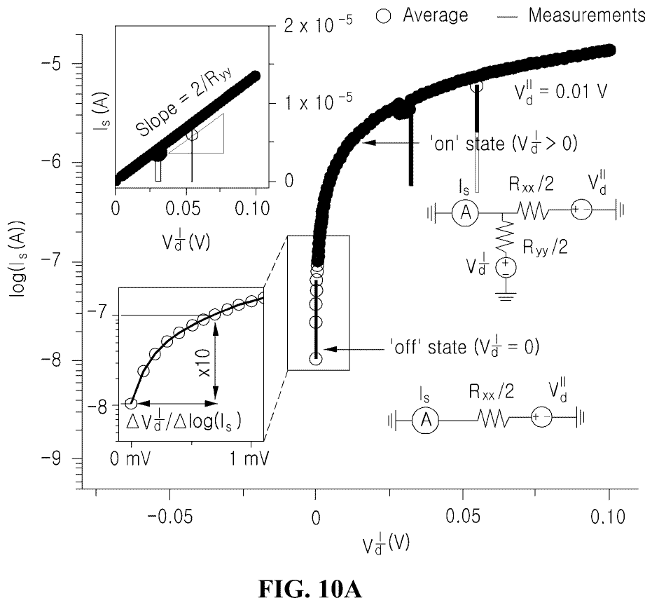

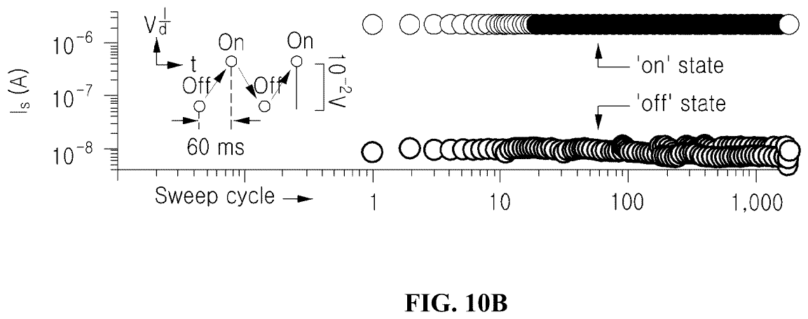

FIG. 10 shows experimental data analyzing the characteristics of an all-metal three-terminal electrical switching device according to an embodiment of the disclosure.

Referring to FIG. 10, the on/off state and subthreshold swing characteristics of the all-metal three-terminal electrical switching device can be confirmed.

FIG. 11 is a graph showing that the mathematical prediction of the device's on/off ratio according to the applied voltage matches experimental data, and that the on/off ratio can be increased by up to 10⁷ times or more depending on the driving voltage.

Referring to FIG. 11, it can be confirmed that the on-off ratio can be increased by up to 10⁷ times or more depending on the voltages (V_{d}^{⊥}, V_{d}^{∥}) applied to the two terminals of an all-metal three-terminal electrical switching device.

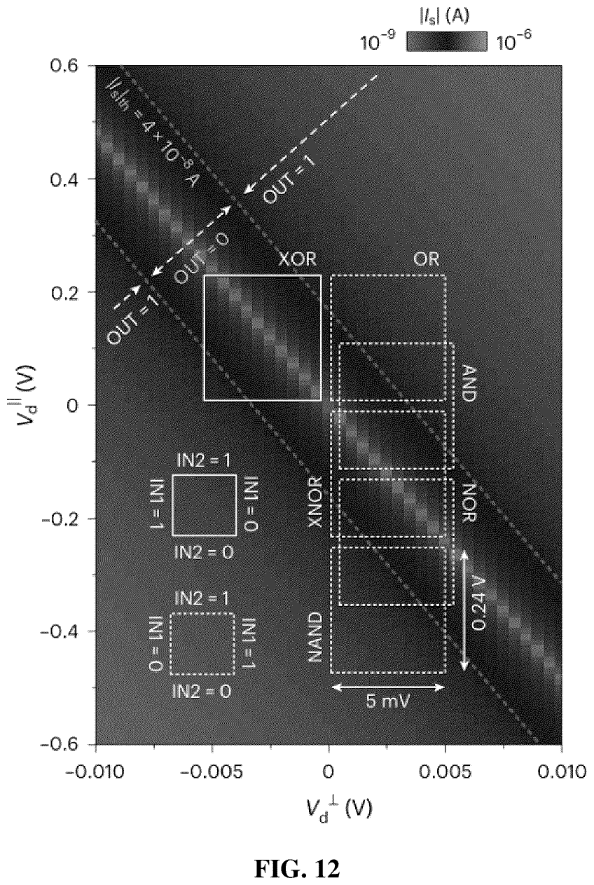

FIG. 12 is a graph showing the current (Iₛ) values as a function of the first drain voltage (V_{d}^{⊥}) and second drain voltage (V_{d}^{∥}).

Referring to FIG. 12, the areas marked by white rectangles in the graph indicate that controlling the two input voltages within those areas enables the implementation of the logical operations indicated by the rectangles.

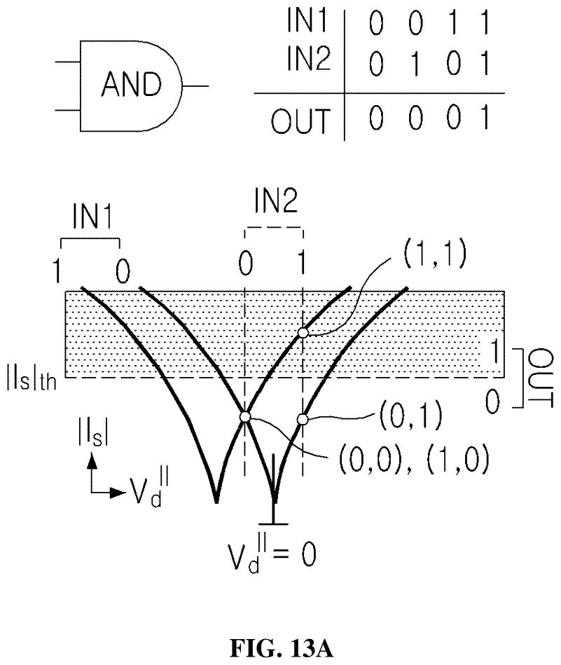

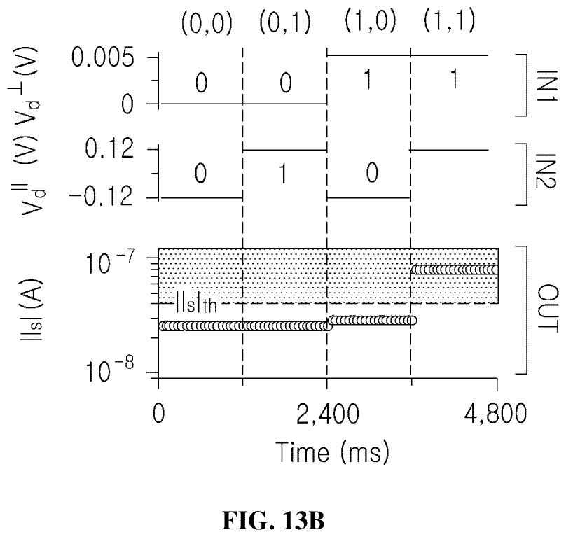

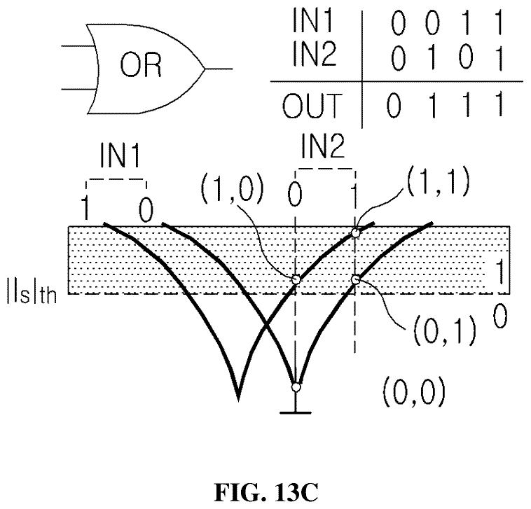

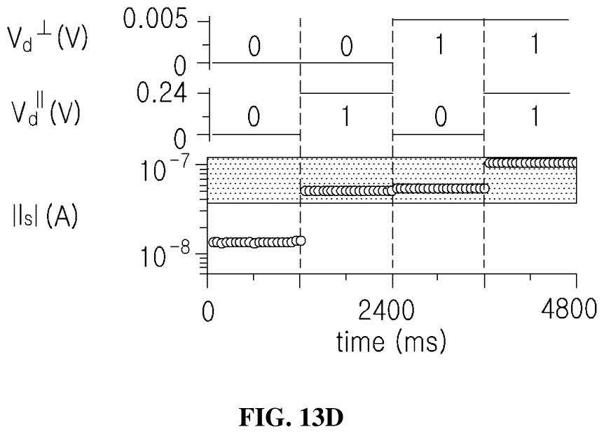

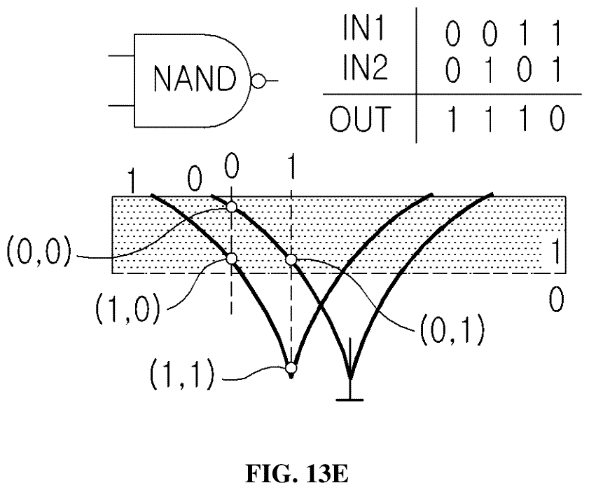

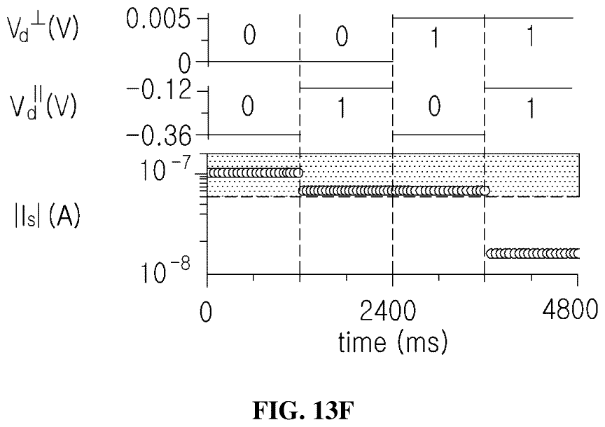

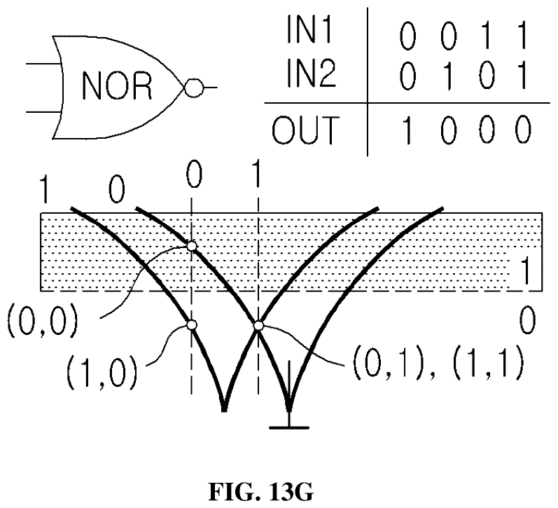

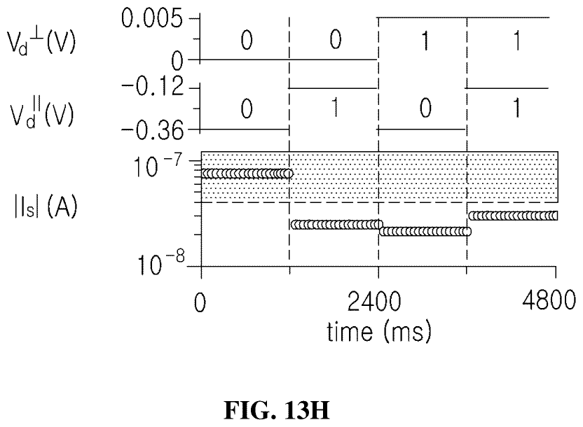

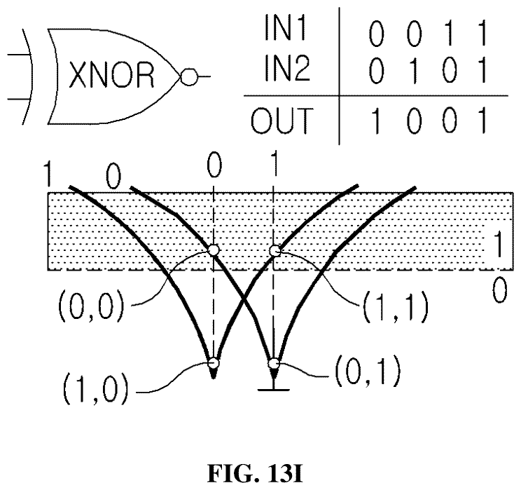

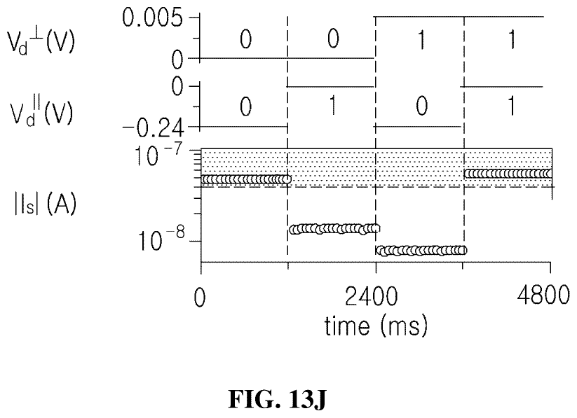

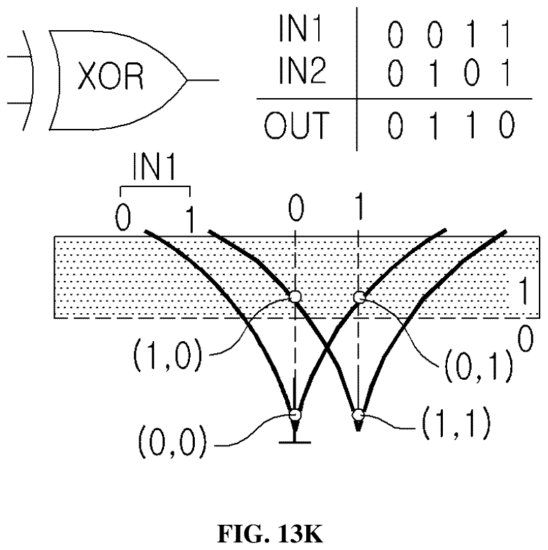

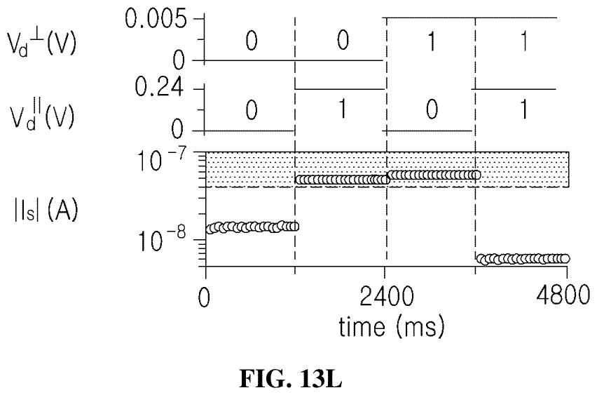

FIG. 13 illustrates the relationship between the input voltages (V_{d}^{⊥}, V_{d}^{∥}) and the output current (Iₛ) for each of the six rectangular areas shown in FIG. 12, as well as examples of implementing each logical operation based on these relationships.

More specifically, referring to FIG. 13,
when for the first drain voltage (V_{d}^{⊥}), two voltages are selected at 5 mV intervals within −5 mV, 0 mV, and 5 mV and defined as “IN1=0” and “IN1=1”, respectively, for the second drain voltage (V_{d}^{∥}), two voltages are selected at 0.24 V intervals within −0.48 V, −0.36 V, −0.24 V, −0.12 V, 0 V, 0.12 V, and 0.24 V and defined as “IN2=0” and “N2=1”, respectively,
for the current (Iₛ) flowing within the device, the case of |Iₛ|<4×10⁻⁸ A is defined as the off-current level (OUT=0, ‘0’), and the case of |Iₛ|>4×10⁻⁸ A is defined as the on-current level (OUT=1, ‘1’),
a logical operation can be implemented through the relationship between the two input voltages and the output current.

### 1. AND Logic Gate Implementation (FIGS. 13a and b)

When V_{d}^{⊥}=0 mV is defined as “IN1=0”, V_{d}^{⊥}=5 mV as “IN1=1”,
V_{d}^{∥}=−0.12 V as “IN2=0”, and V_{d}^{∥}=0.12 V as “IN2=1”,
it is possible to implement AND logic in which “OUT=0” is output when [(IN1, IN2)=(0, 0), (0, 1), (1, 0)], and
“OUT=1” is output when [(IN1, IN2)=(1, 1)].

### 2. OR Logic Gate Implementation (FIGS. 13c and d)

When V_{d}^{⊥}=0 mV is defined as “IN1=0”, V_{d}^{∥}=5 mV as “IN1=1”,
V_{d}^{∥}=0 V as “IN2=0”, and V_{d}^{∥}=0.24 V as “IN2=1”,
it is possible to implement OR logic in which “OUT=0” is output when [(IN1, IN2)=(0, 0)], and
“OUT=1” is output when [(IN1, IN2)=(0, 1), (1, 0), (1, 1)].

### 3. NAND Logic Gate Implementation (FIGS. 13e and f)

When V_{d}^{⊥}=0 m V is defined as “IN1=0”, V_{d}^{∥}=5 mV as “IN1=1”,
V_{d}^{∥}=−0.48 V as “IN2=0”, and V_{d}^{∥}=−0.24 V as “IN2=1”,
it is possible to implement NAND logic in which “OUT=0” is output when [(IN1, IN2)=(1, 1)], and
“OUT=1” is output when [(IN1, IN2)=(0, 0), (0, 1), (1, 0)].

### 4. NOR Logic Gate Implementation (FIGS. 13g and h)

When V_{d}^{⊥}=0 mV is defined as “IN1=0”, V_{d}^{∥}+=5 mV as “IN1=1”,
V_{d}^{∥}=−0.36 V as “IN2=0”, and V_{d}^{∥}=−0.12 V as “IN2=1”,
It is possible to implement NOR logic in which “OUT=0” is output when [(IN1, IN2)=(0, 1), (1, 0), (1, 1)], and
“OUT=1” is output when [(IN1, IN2)=(0, 0)].

### 5. XNOR Logic Gate Implementation (FIGS. 13i and j)

When V_{d}^{⊥}=0 mV is defined as “IN1=0”, V_{d}^{⊥}=5 mV as “IN1=1”,
V_{d}^{∥}=−0.24 V as “IN2=0”, and V_{d}^{∥}=0 V as “IN2=1”,
it is possible to implement XNOR logic in which “OUT=0” is output when [(IN1, IN2)=(0, 1), (1, 0)], and
“OUT=1” is output when [(IN1, IN2)=(0, 0), (1, 1)].

### 6. XOR Logic Gate Implementation (FIGS. 13k and l)

When V_{d}^{⊥}=0 mV is defined as “IN1=0”, V_{d}^{⊥}=−5 mV as “IN1=1”,
V_{d}^{∥}=0 V as “IN2=0”, and V_{d}^{∥}=0.24 V as “IN2=1”,
it is possible to implement XOR logic in which “OUT=0” is output when [(IN1, IN2)=(0, 1), (1, 0)], and
“OUT=1” is output when [(IN1, IN2)=(0, 0), (1, 1)].

Likewise, it can be confirmed that an all-metal three-terminal electrical switching device that does not include a dielectric layer according to an embodiment of the disclosure can operate without using charging and discharging of a capacitor, and can operate as a low-voltage, high-speed device while achieving a high on-off ratio and implementing logical operations.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

What is claimed is:

1. A method for manufacturing a metal nanosheet having in-plane electrical anisotropy, comprising:
providing a template having a two-dimensional layered structure with a interlayer height; and
electroplating metal in an interlayer space of the template,
wherein nucleation occurs in the interlayer space of the template, and the interlayer height is fixed.

2. The method for manufacturing the metal nanosheet having the in-plane electrical anisotropy of claim 1, wherein the providing the template comprises:
forming a pair of glass layers on upper and lower surfaces of the template; and
sealing three of side surfaces of the template with epoxy resin.

3. The method for manufacturing the metal nanosheet having the in-plane electrical anisotropy of claim 1, wherein the providing the template comprises:
attaching a negative electrode to one end of the template; and
connecting a wire to the negative electrode.

4. The method for manufacturing the metal nanosheet having the in-plane electrical anisotropy of claim 3, wherein in the electroplating the metal, the nucleation occurs on a surface of the negative electrode, and ion diffusion proceeds through the interlayer space of the template, resulting in unidirectional crystal growth.

5. The method for manufacturing the metal nanosheet having the in-plane electrical anisotropy of claim 1, wherein a grain boundary of the metal plated through the electroplating of the metal is aligned parallel to upper and lower surfaces of the template.

6. The method for manufacturing the metal nanosheet having the in-plane electrical anisotropy of claim 1, wherein the interlayer height of the template is greater than an ion size of the metal to be plated, but smaller than an ion size of the metal in a hydrated state.

7. The method for manufacturing the metal nanosheet having the in-plane electrical anisotropy of claim 1, wherein the interlayer height of the template is in a range of 2.5 Å to 7.5 Å.

8. The method for manufacturing the metal nanosheet having the in-plane electrical anisotropy of claim 1, wherein the template is an insulator having a two-dimensional van der Waals gap, and is composed of at least one selected from a group consisting of graphene oxide (GO), vermiculite, and boron nitride (hBN).

9. The method for manufacturing the metal nanosheet having the in-plane electrical anisotropy of claim 1, wherein the metal comprises at least one selected from a group consisting of Mg, Al, Cr, Mn, Fe, Co, Ni, Cu, Zn, Rb, Sr, Ag, Cd, Cs, Ba, La, and Pb.

10. A metal nanosheet formed by the method of claim 1, wherein the metal nanosheet has the in-plane electrical anisotropy.

11. The metal nanosheet of claim 10, wherein the metal comprises at least one selected from a group consisting of Mg, Al, Cr, Mn, Fe, Co, Ni, Cu, Zn, Rb, Sr, Ag, Cd, Cs, Ba, La, and Pb.

12. An all-metal three-terminal electrical switching device, comprising:
a metal nanosheet having in-plane electrical anisotropy; and
a plurality of electrodes connected to the metal nanosheet,
wherein the plurality of electrodes comprises a source electrode, a first drain electrode (⊥), and a second drain electrode (∥).

13. The all-metal three-terminal electrical switching device of claim 12, wherein the metal nanosheet has higher electrical conductivity in a direction parallel to a grain alignment axis than in a direction perpendicular to the grain alignment axis.

14. The all-metal three-terminal electrical switching device of claim 12, wherein the first drain electrode (⊥) is connected in a direction parallel to a grain alignment axis of the metal nanosheet, and the second drain electrode (∥) is connected in a direction perpendicular to the grain alignment axis of the metal nanosheet.

15. The all-metal three-terminal electrical switching device of claim 12, wherein an on/off ratio of the all-metal three-terminal electrical switching device is determined by formula 1:
$$1 + \frac{Rxx V ⊥ d}{Ryy V \vert \vert d} . \qquad [ Equation 1 ]$$

16. The all-metal three-terminal electrical switching device of claim 12, wherein an on/off ratio of the all-metal three-terminal electrical switching device is 10⁷ or more.

17. The all-metal three-terminal electrical switching device of claim 12, wherein a magnitude of a current (Iₛ) flowing through the all-metal three-terminal electrical switching device changes according to a voltage applied to the first drain electrode (⊥) and the second drain electrode (∥), and
wherein if the magnitude of the current (Iₛ) is less than a predetermined threshold, it is defined as an off state, and if the magnitude of the current exceeds the predetermined threshold, it is defined as an on state.

18. The all-metal three-terminal electrical switching device of claim 16, wherein a predetermined threshold is set within a range of 10⁻⁹ A to 10⁻⁶ A.

19. The all-metal three-terminal electrical switching device of claim 17, wherein in the all-metal three-terminal electrical switching device, by setting application conditions of a first drain voltage (V_{d}^{™}) and a second drain voltage (V_{d}^{∥}), one of a plurality of logical operations selected from a group consisting of AND, OR, NAND, NOR, XOR, and XNOR is implementable.
